(19) United States
(12) Patent Application Publication
(10) Pub. No.: US 2009/0045839 A1
(43) Pub. Date: Feb. 19, 2009

(54) ASIC LOGIC LIBRARY OF FLEXIBLE LOGIC BLOCKS AND METHOD TO ENABLE ENGINEERING CHANGE

(75) Inventors: Robert D. HERZL, South Burlington, VT (US); Robert S. Horton, Colchester, VT (US); Kenneth A. Lauricella, Colchester, VT (US); David W. Milton, Underhill, VT (US); Clarence R. Ogilvie, Huntington, VT (US); Paul M. Schanely, Essex Junction, VT (US); Nitin Sharma, South Burlington, VT (US); Tad J. Wilder, South Hero, VT (US); Charles B. Winn, Colchester, VT (US)

Correspondence Address: GREENBLUM & BERNSTEIN, P.L.C., 1950 ROLAND CLARKE PLACE, RESTON, VA, 20191, US

(73) Assignee: INTERNATIONAL BUSINESS MACHINES CORPORATION, Armonk, NY (US)

(21) Appl. No.: 11/876,263

(22) Filed: Oct. 22, 2007

Related U.S. Application Data
(63) Continuation-in-part of application No. 11/838,929, filed on Aug. 15, 2007.

(51) Int. Cl. H03K 19/177; G06F 17/50

(52) U.S. Cl. 326/39; 716/18

(57) ABSTRACT

A chip design methodology and an integrated circuit chip. The methodology includes providing a plurality of logic gates in a net list, wherein each of the logic gates comprises at least one spare input, synthesizing the net list, and connecting the spare inputs for performing an engineering change late in the design process. The invention is also directed to a design structure on which a circuit resides.

### CROSS-REFERENCE TO RELATED APPLICATIONS

The present application is a continuation in part of U.S. application Ser. No. 11/838,929, filed on Aug. 15, 2007, the disclosure of which is expressly incorporated by reference herein in its entirety.

### FIELD OF THE INVENTION

An application specific integrated circuit (ASIC) and method for forming such an integrated circuit chip, particularly when engineering changes are made late in the design process. The invention is also directed to a design structure on which a circuit resides.

### BACKGROUND OF THE INVENTION

An application specific integrated circuit (ASIC) is an integrated circuit designed or customized for a specific use or task. Generally, a customer or client requests a manufacturer or ASIC design center to fabricate an ASIC to perform specific logic. The customer may provide a “net list,” which represents the desired logic operation for the application, or some other representation of the logic for performing the desired task to a designer or engineer. The designer or engineer takes the customer's logic and synthesizes it into gate logic. This gate logic is then placed and routed to form a physical design of the chip, which can take, e.g., many weeks to months to complete.

During the placing and routing procedure, it is not unusual for the customer to request engineering changes for the logic, e.g., in an effort to improve the ASIC functionality. In this regard, it can be difficult, after logic synthesis and the initial physical design process, to change the placed and routed gate logic. As a result, incorporating the engineering changes into the ASIC may generally result in a very complicated and lengthy ordeal for the designer/engineer. Moreover, gate logic cannot generally simply be replaced, since changing gate logic can result in different timing characteristics between the gates that must also be considered in the new gate logic.

The underlying obstacles to putting in engineering changes to a chip have for a long time plagued designers. From distilling down the minimal change in a net list (when the change was made to register transfer logic (RTL)) to rewiring gates on an existing placement the change is always a timely complicated process and does not lend itself to automation.

### SUMMARY OF THE INVENTION

According to an aspect of the invention, a chip design methodology includes providing a plurality of logic gates in a net list, in which each of the logic gates includes at least one spare input, synthesizing the net list, and connecting the spare inputs for performing an engineering change late in the design process.

In accordance with another aspect of the invention, a method for chip design includes selecting at least one gate in a synthesized gate logic, and replacing the at least one selected gate with a flexible logic block wired to function as the at least one selected gate. The flexible logic block is wired to function as the at least one selected gate includes at least one unused input.

According to still another aspect of the invention, an integrated circuit chip includes synthesized gate logic composed of a plurality of gates, in which each gate has an associated function, and at least one flexible logic block is arranged to replace at least one of the plurality of gates. The at least one flexible logic block is wired to perform the associated function of at least one of the plurality of gates replaced and includes at least one unused input.

In yet another aspect of the invention, a design structure is embodied in a machine readable medium for designing, manufacturing, or testing a design. The design structure comprises: synthesized gate logic composed of a plurality of gates, in which each gate has an associated function; and at least one flexible logic block arranged to replace at least one of the plurality of gates. The at least one flexible logic block is wired to perform the associated function of at least one of the plurality of gates replaced and includes at least one unused input.

In embodiments, the design structure comprises a netlist, which describes the circuit. The design structure resides on storage medium as a data format used for the exchange of layout data of integrated circuits. The design structure includes at least one of test data files, characterization data, verification data, or design specifications. The design structure further comprises a component for: providing a plurality of logic gates in a net list, wherein each of the logic gates comprises at least one spare input; synthesizing the net list; and connecting the spare inputs for performing an engineering change late in the design process.

### BRIEF DESCRIPTION OF THE DRAWINGS

The present invention is described in the detailed description which follows, in reference to the noted plurality of drawings by way of non-limiting examples of exemplary embodiments of the present invention.

FIG. 1 illustrates an exemplary physical structure for an application specific integrated circuit (ASIC) chip according to an embodiment of the invention;

FIG. 2 illustrates examples of normal ASIC gates and suitable replacement flexible logic blocks (FLBs) in accordance with the invention;

FIG. 3 illustrates an exemplary flow diagram for performing an embodiment of the invention;

FIG. 4 illustrates a graphical illustration of the flow diagram depicted in FIG. 3; and

FIG. 5 is a flow diagram of a design process used in semiconductor design, manufacturing, and/or test.

### DETAILED DESCRIPTION OF THE EMBODIMENTS OF THE INVENTION

The invention is directed to reducing the effort to incorporate engineering changes requested late in the design cycle of an application specific integrated circuit (ASIC).

According to the invention, flexible logic blocks (FLBs) can be inserted into synthesized logic in an ASIC to function as normal gate logic and to enable engineering and/or design changes late in the design cycle. The FLBs can replace logic gates in risky logic. The ASIC can also include additional unused FLBs to assist in the late changes in the design cycle.

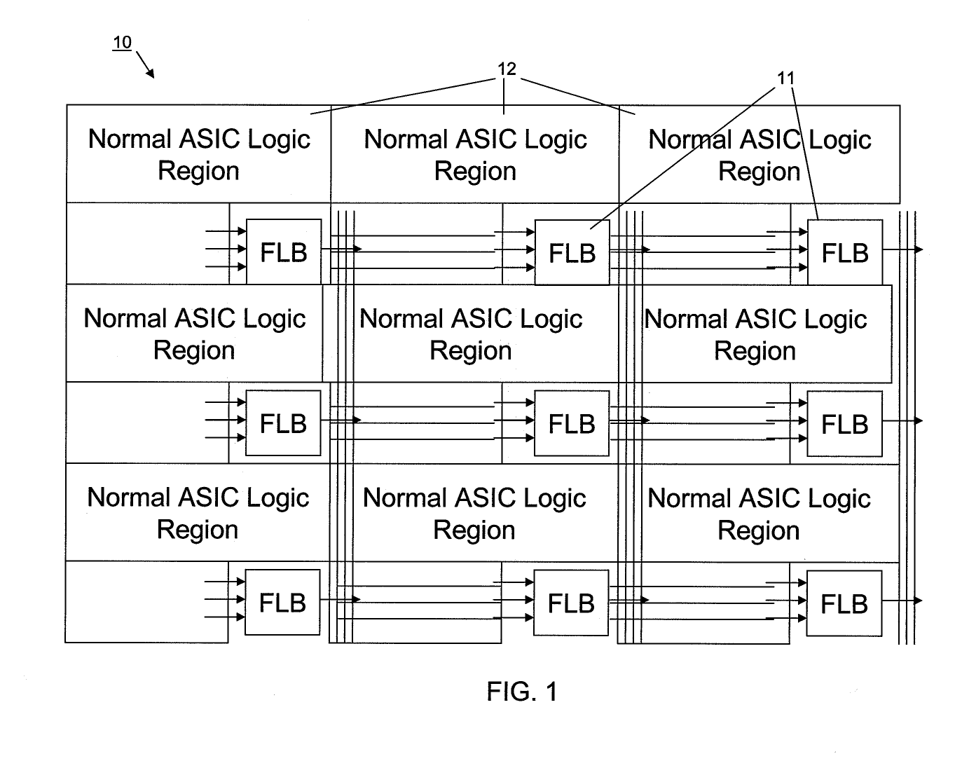

FIG. 1 illustrates the physical structure of an application specific integrated circuit (ASIC) structure according to the invention. As shown, flexible logic blocks (FLBs) 11 can be distributed or sprinkled across chip 10 with normal ASIC logic 12, e.g., in a regular array or predefined pattern. FLBs 11 and normal (standard) ASIC logic 12 can be interconnected (not shown) on chip 10 in order to perform the desired logic of the ASIC. Alternatively, FLBs 11 can be arranged in a predefined region of chip 10 and can be interconnected with normal ASIC logic 12 throughout chip 10 to perform the desired ASIC functionality.

According to the invention, FLBs are enhanced logic function gates with at least one additional function wired to be initially deactivated, e.g., through extra tied inputs tied to an inactive state. Thus, FLBs 11 arranged across chip 10 or in a predefined region of chip 10 can be interconnected with the normal ASIC logic and yet allow for easy changes to their function and operation. Further, to facilitate the late changes to the design, e.g., after the chip 10 has been placed and routed, FLBs 11 provided on chip 10 can include used and unused logic gates. Because of the unused or deactivated functions associated with the FLBs, the use of FLBs 11 allow for engineering changes to the ASIC logic, even if not made until late in the design cycle. Moreover, the engineering changes can be effected through wire only changes, thereby avoiding timing problems generally associated with replacing and/or adding logic gates to the chip.

According to aspects of the invention, the use of FLBs 11 and their associated reconnection techniques to utilize initially unused logic allow changes to be easily made to FLB function even after the chip is manufactured. Wiring to and from FLBs 11 can stretch around chip 10 or the predefined region of chip 10 to enable easy connections to and from other standard ASIC function placed and wired on chip 10. Further, for ease of modifying the logic, it may be advantageous to build much of the original logic function on chip 10 from FLBs 11.

ASIC chips are generally requested by a customer who provides a “net list” representing the desired logic for the application to be performed. The manufacturer of the chip can synthesize gate logic from the customer net list, which can be formed in, e.g., register transfer logic (RTL). From this gate logic, it may be advantageous for the designer to identify risky pieces of logic or high risk areas inside the chip. Further, in accordance with the invention, it can be advantageous to substitute FLBs for the risky logic or to place FLBs in the identified high risk areas. By way of example, risky pieces of logic or high risk areas inside chip may include, but are certainly not limited to newer cores, e.g., cores which will be seeing silicon for the first time, glue logic areas, i.e., new or changed logic that is being used to connect cores, areas inside the chip where a level of confidence is low, i.e., in terms of design and verification efforts possibly attributable to numerous factors, e.g., constraining time to market conditions, etc., and a high occurrence of functional verification bugs found in a particular area.

Moreover, FLBs can also be synthesized, placed and routed in place of normal ASIC gates, i.e., not merely to replace risky logic or to be placed in high risk areas. In this event, such FLB gates may have some of inputs and outputs wired to perform the functioning logic of the normal ASIC gate and have additional inputs, and perhaps even outputs, that are at least initially appropriately tied off so the FLB functions as the normal ASIC gate it replaces. With this design, should a change, e.g., an engineering change, be required or requested by the customer or designer later in the design cycle, e.g., after placing and routing, the function of the FLB can be easily changed or effected through wire only changes to the inputs and/or outputs of the FLB.

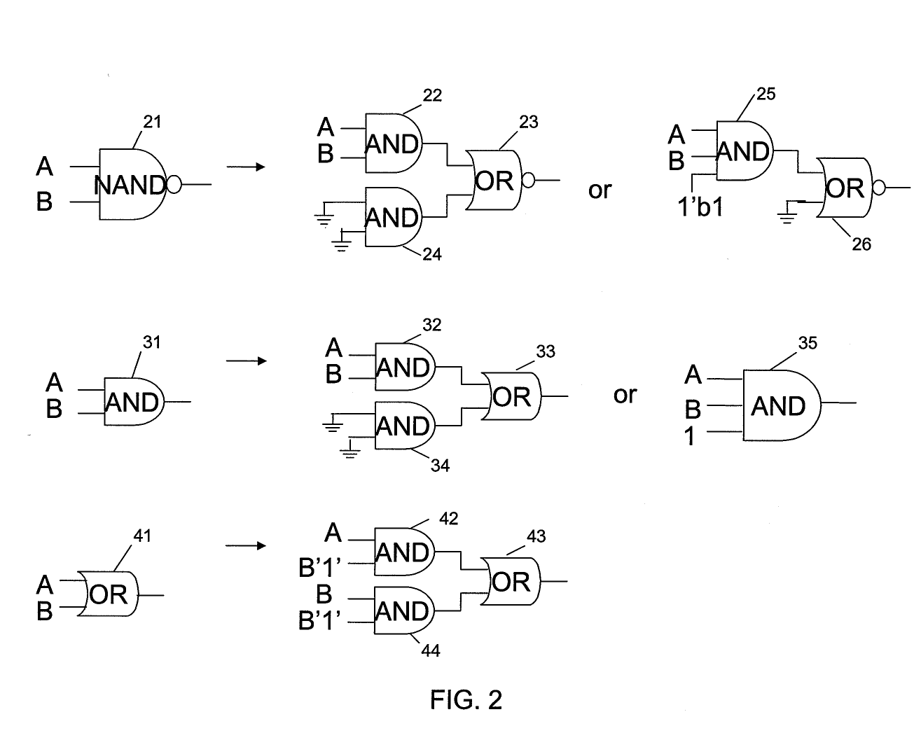

After a risky piece of logic or a high risk area has been identified, or if it is simply desired to replace normal logic with an FLB, the specific gates of this identified logic (risky or normal) or area can be isolated and synthesized or formed with FLBs or combinations of FLBs and normal logic gates. As noted above, while FLBs can be very complex functions, e.g., programmable MUX structures, NAND and NOR gates with and/or inverted gates (AOIs) with appropriately tied off inputs, they can change their function through a mere change of wiring. Moreover, it may be advantageous to arrange the tied inputs on metal layers where they can be accessed and, therefore, easily changed. FIG. 2 illustrates examples of normal ASIC gates and suitable replacement FLBs that can be used in place them.

By way of non-limiting example, FIG. 2 illustrates a normal or standard logic block and a suitable replacement FLB at least initially wired to function as the normal logic block it can replace. According to an aspect of the invention, a standard NAND gate 21 having inputs A and B can be replaced with an FLB formed of an AND gate 22 with inputs A and B and an output coupled to an OR inverted gate 23. Another AND gate 24 has inputs tied to ground and an output coupled to the OR inverted gate 23. Also, NAND gate 21 can be formed as an AND-OR inverted (AOI) in which AND gate 25 has inputs A and B and 1′B1 and an output coupled to OR inverted gate 26. The other input to OR inverted gate 26 is tied to ground. According to another aspect of the invention, a standard AND gate 31 having inputs A and B can be replaced with an FLB formed of an AND gate 32 with inputs A and B and an output coupled to an OR gate 33. Another AND gate 34 has inputs tied to ground and an output coupled to the OR gate 33. Also, AND gate 31 can be formed as by AND gate 35 having inputs A and B and 1. Moreover, standard OR gate 41 having inputs A and B can be replaced with an AND gate 42 with inputs A and B′1′ and an output coupled to an OR gate 43. Another AND gate 44 has inputs B and B′1′ and an output coupled to the OR gate 43. It is understood that additional and even more complicated FLBs can be formed for replacing standard logic blocks without departing from the spirit and scope of the invention. Further, while FIG. 2 illustrates exemplary basic standard logic block, it is understood other FLBs can be designed and initially wired for replacing other standard logic blocks that have not been illustrated here without departing from the scope and spirit of the invention.

As shown in the illustrations of the replacement FLB in FIG. 2, the inputs and outputs of the FLBs are initially wired not only to perform the functioning logic of the normal ASIC gate it replaces but also to include additional inputs that are appropriately tied off, e.g., to ground. As discussed above, this design allows for easy alteration of the functioning of the FLBs through the wiring of the gates. Should a change, e.g., an engineering change, be required later in the design cycle, e.g., after placing and routing, the function of the FLB or the inputs and/or outputs of the FLB can be easily added to or changed with wire only changes.

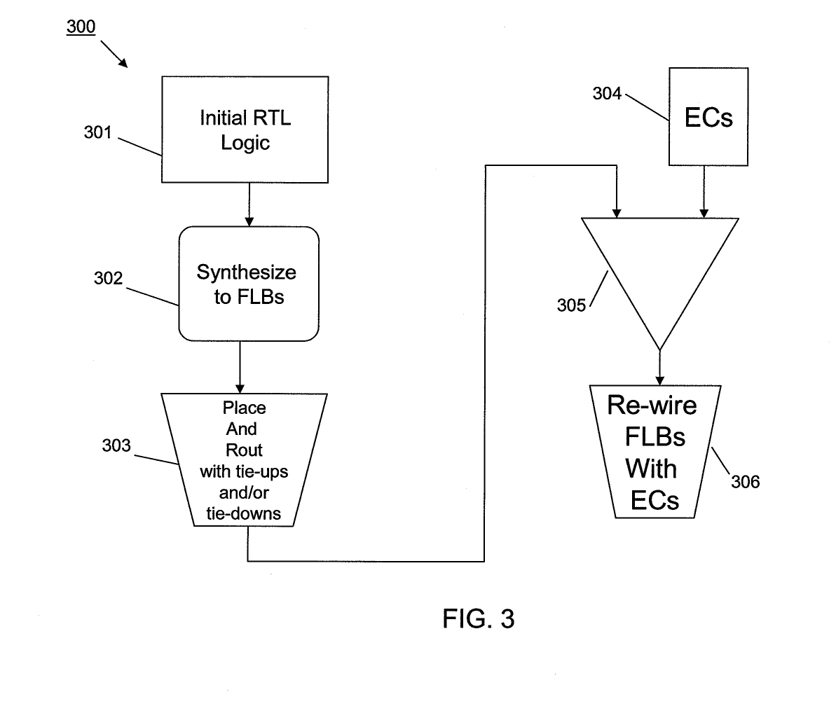

FIG. 3 shows a flow diagram 300 for the design of an ASIC chip according to the invention. The initial RTL logic is created from the customer's desired logic for the chip application or net list at step 301. From the RTL logic, the designer can determine whether there are any risky pieces of logic or high risk areas in the designed logic, and decide which of the normal gates associated with these risky pieces of logic or high risk areas are to be replaced with FLBs at step 302. It is also understood the designer at step 302 can decide to replace normal gates with FLBs, regardless of whether the normal gates are associated with risky pieces of logic or high risk areas. The FLBs can be placed on the chip and routed at step 303 to be initially wired to function as the normal gate it replaces. In this regard, the routing of the FLBs includes tie-ups and/or tie-downs on the additional inputs as these additional inputs are not required for functioning as the normal gate.

Step 304 represents some time later in the design process, when engineering changes devised by the customer or chip designer are received at step 305. The engineering changes are compared to the place and routed gates on the chip to determine the manner in which the FLBs can be rewired at step 306 to satisfy the engineering changes.

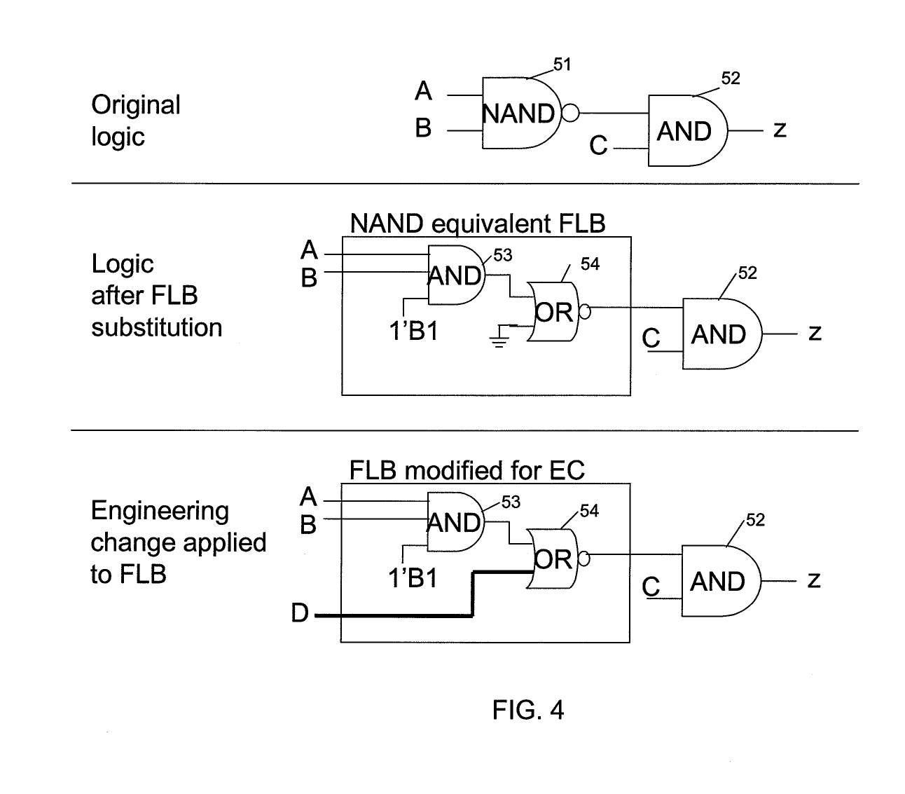

An example of the above-discussed flow diagram is graphically illustrated in FIG. 4. As shown, the original logic can includes a NAND gate 51 with inputs A and B and an output coupled as an input to AND gate 52. AND gate 52 also includes an input C and an output Z. The designer can decide to replace NAND gate 51 with an equivalent FLB. A suitable FLB replacement for a NAND gate is illustrated, e.g., in FIG. 2 and this FLB can be substituted for NAND gate 51 to be placed and routed with AND gate 52, as shown in FIG. 4. As a result, NAND gate 51 can be replaced by an AOI in which AND gate 53 has inputs A and B and 1′B1 and an output coupled to OR inverted gate 54. The other input to OR inverted gate 54 is at least initially tied to ground so the FLB initially functions as the NAND gate it replaces. Subsequently to an engineering change, the input to OR gate 54 can be removed from ground and receive input D. Moreover, as no new logic is added to address the engineering change, there is no disruption in the timing of the logic.

Further, when engineering changes are requested in logic composed essentially entirely of FLBs, it can be easy to make these changes through wire only changes.

A further process can be performed to insure engineering changes can be made easily in any area of risky logic. Accordingly, this process may be performed during the placing and routing to evenly distribute the FLB's or extra logic. This process can also be used in conjunction with previously described FLB insertion or by itself. Initially, a placement run can be performed, and the area can then be subdivided into arbitrarily small regular regions. In this regard, the smaller the subdivided regions, the more spare logic can be available for engineering changes. Within each region, a logic block can be selected to change from its current function to either a superset of this function or to an FLB. For instance, a two-input AND can be converted to a 3-input AND with the 3rd leg tied high. This logic can then be re-placed on the chip. As a result of this change, a relatively uniform spread of logic with spare inputs (tied inactive) throughout the area is attained. This design, along with some spare wires, will make it easier to satisfy minor engineering changes with metal-only changes. An additional advantage of this further process includes that it can be performed without requiring access to the original RTL.

The circuit as described above is part of the design for an integrated circuit chip. The chip design is created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer transmits the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed. Moreover, the process as described above is used in the fabrication of integrated circuit chips.

The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

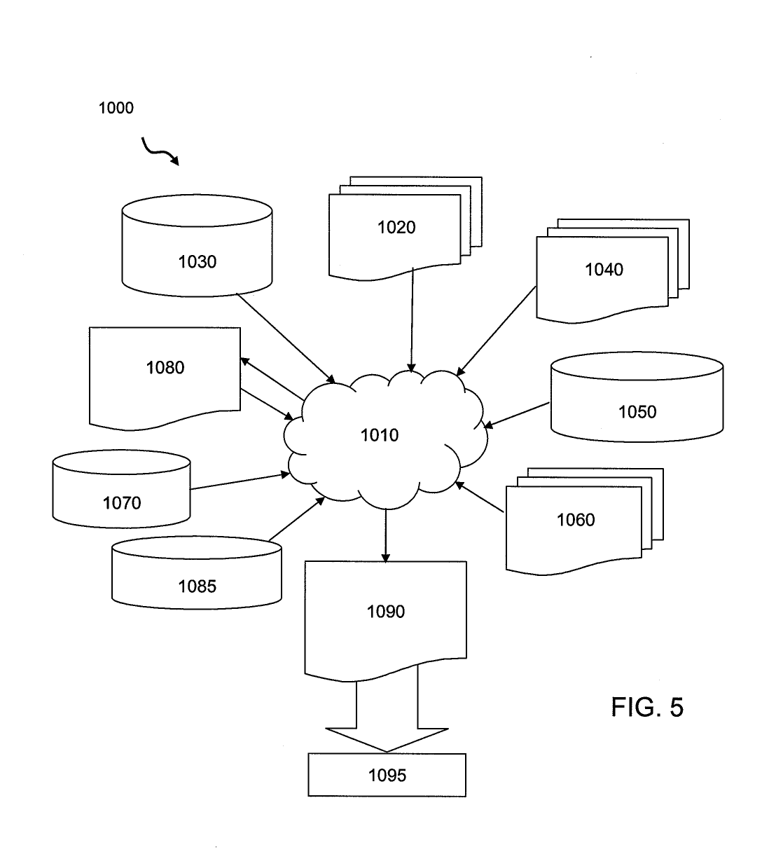

FIG. 5 is a flow diagram of a design process used in semiconductor design, manufacturing, and/or test. FIG. 5 shows a block diagram of an example design flow 1000. Design flow 1000 may vary depending on the type of IC being designed. For example, a design flow 1000 for building an application specific IC (ASIC) may differ from a design flow 1000 for designing a standard component. Design structure 1020 is preferably an input to a design process 1010 and may come from an IP provider, a core developer, or other design company or may be generated by the operator of the design flow, or from other sources. Design structure 1020 comprises the circuit and/or structure of the present invention, e.g., see FIG. 1, for example, in the form of schematics or HDL, a hardware-description language (e.g., Verilog, VHDL, C, etc.). Design structure 1020 may be contained on one or more machine readable medium. For example, design structure 1020 may be a text file or a graphical representation of the circuit and/or structure of the present invention. Design process 1010 preferably synthesizes (or translates) the circuit and/or structure of the present invention, into a netlist 1080, where netlist 1080 is, for example, a list of wires, transistors, logic gates, control circuits, I/O, models, etc. that describes the connections to other elements and circuits in an integrated circuit design and recorded on at least one of machine readable medium. This may be an iterative process in which netlist 1080 is resynthesized one or more times depending on design specifications and parameters for the circuit.

Design process 1010 may include using a variety of inputs; for example, inputs from library elements 1030 which may house a set of commonly used elements, circuits, and devices, including models, layouts, and symbolic representations, for a given manufacturing technology (e.g., different technology nodes, 32 nm, 45 nm, 90 nm, etc.), design specifications 1040, characterization data 1050, verification data 1060, design rules 1070, and test data files 1085 (which may include test patterns and other testing information). Design process 1010 may further include, for example, standard circuit design processes such as timing analysis, verification, design rule checking, place and route operations, etc. One of ordinary skill in the art of integrated circuit design can appreciate the extent of possible electronic design automation tools and applications used in design process 1010 without deviating from the scope and spirit of the invention. The design structure of the invention is not limited to any specific design flow.

Design process 1010 preferably translates an embodiment of the invention as shown in the accompanying figures such as, for example, FIG. 1, along with any additional integrated circuit design or data (if applicable), into a second design structure 1090. Design structure 1090 resides on a storage medium in a data format used for the exchange of layout data of integrated circuits (e.g. information stored in a GDSII (GDS2), GL1, OASIS, or any other suitable format for storing such design structures). Design structure 1090 may comprise information such as, for example, test data files, design content files, manufacturing data, layout parameters, wires, levels of metal, vias, shapes, data for routing through the manufacturing line, and any other data required by a semiconductor manufacturer to produce an embodiment of the invention as shown in the accompanying figures such as, for example, FIG. 1. Design structure 1090 may then proceed to a stage 1095 where, for example, design structure 1090: proceeds to tape-out, is released to manufacturing, is released to a mask house, is sent to another design house, is sent back to the customer, etc.

While the invention has been described in terms of a preferred embodiment, those skilled in the art will recognize that the invention can be practiced with modifications within the spirit and scope of the appended claims.

What is claimed:

1. A design structure embodied in a machine readable medium for designing, manufacturing, or testing a design, the design structure comprising:
synthesized gate logic composed of a plurality of gates, in which each gate has an associated function; and
at least one flexible logic block arranged to replace at least one of the plurality of gates,
wherein the at least one flexible logic block is wired to perform the associated function of at least one of the plurality of gates replaced and includes at least one unused input.

2. The design structure of claim 1, wherein the design structure comprises a netlist, which describes the circuit.

3. The design structure of claim 1, wherein the design structure resides on storage medium as a data format used for the exchange of layout data of integrated circuits.

4. The design structure of claim 1, wherein the design structure includes at least one of test data files, characterization data, verification data, or design specifications.

5. A design structure embodied in a machine readable medium for designing, manufacturing, or testing a design, the design structure comprising:
means for providing a plurality of logic gates in a net list, wherein each of the logic gates comprises at least one spare input;
means for synthesizing the net list; and
means for connecting the spare inputs for performing an engineering change late in the design process.
